(19) United States
(12) Patent Application Publication
(10) Pub. No.: US 2021/0396777 A1
(43) Pub. Date: Dec. 23, 2021

(54) SENSOR DEVICE AND CIRCUIT MEANS AND METHOD FOR CONTROLLING THE ENERGY CONSUMPTION OF A SENSOR DEVICE

(71) Applicant: Robert Bosch GmbH, Stuttgart (DE)

(72) Inventors: Ruslan Khalilyulin, Muenchen (DE); Andrea Visconti, Muenchen (DE); Artjom Kosov, Muenchen (DE); Dorde Cvejanovic, Muenchen (DE)

(21) Appl. No.: 17/351,645

(22) Filed: Jun. 18, 2021

(30) Foreign Application Priority Data
Jun. 23, 2020 (DE) 102020207740.1

(51) Int. Cl. G01P 3/00; G01P 15/00; G01L 19/00; G01R 33/00

(52) U.S. Cl. CPC G01P 3/00; G01R 33/0023; G01L 19/00; G01P 15/00

(57) ABSTRACT

An energy-efficient sensor device, a circuit arrangement for operating an energy-efficient sensor device, and a method for controlling the energy consumption of a sensor device. In particular, the operating mode of a sensor device is adapted as a function of a temporal change in a received sensor signal.

### CROSS REFERENCE

The present application claims the benefit under 35 U.S.C. § 119 of German Application No. DE 102020207740.1 filed on Jun. 23, 2020, which is expressly incorporated herein by reference in its entirety.

### FIELD

The present invention relates to a sensor device, a circuit arrangement, and a method for controlling the energy consumption of a sensor device.

### BACKGROUND INFORMATION

Sensors generally detect one or multiple surroundings parameters and provide an output signal corresponding to the detected parameter. To detect and process the output signal of a sensor, generally an electrical circuit is necessary, which requires electrical energy. Particularly for battery-operated sensor devices, it is desirable for the sensor devices to have the lowest possible energy consumption.

German Patent Application No. DE 10 2018 200 379 A1 describes a sensor arrangement including at least one sensor element. The sensor arrangement further includes a circuit arrangement for generating sensor data on the basis of the sensor signals, the sensor data being generated in an active mode and no sensor data being generated in a sleep mode.

### SUMMARY

The present invention provides a circuit arrangement for automatically controlling the energy consumption of a sensor device, a sensor device, and a method for automatically controlling the energy consumption of a sensor device. Further advantageous embodiments of the present invention are disclosed herein.

The present invention is based on the finding that the preparation and processing of sensor-detected signals generally require electrical energy. The energy available for processing the sensor signals may be limited. For example, the energy provided for processing the sensor signals may be provided by an electrical energy store, such as for example a battery or the like. It is therefore desirable to keep the energy consumption for the preparation and processing of the sensor signals as low as possible.

The present invention is also based on the finding that sensor-detected measured variables may not permanently be subject to change. The sensor-monitored parameters may possibly be constant over a relatively long period of time, or at least may move within a non-relevant range of values. Depending on the application, in such cases there is no need for the sensor values to be detected and prepared permanently.

In accordance with an example embodiment of the present invention, these findings are taken into account and a processing of sensor signals is provided that is as energy-efficient as possible. In accordance with an example embodiment of the present invention, the output signal of a sensor are monitored, and a downstream preparation and/or processing of the sensor signal is/are activated only when the sensor signal indicates a significant change in the parameter to be monitored.

In addition or as an alternative, the preparation or processing of the sensor signal may be adapted according to the temporal change in the sensor signal. For example, in the case of a minor temporal change in the sensor signal, the downstream processing may be carried out only at a low clock rate. Only a lower electronic power is required for this processing at a low clock rate. In contrast, in the case of a high temporal change in the sensor signal, the processing or preparation of the sensor signal may be adapted accordingly in order at all times to be able to ensure a desired required accuracy even in such cases.

In accordance with an example embodiment of the present invention, if, when monitoring the temporal change in the sensor signal, it is established that the sensor signal does not change or at least does not change significantly, the downstream preparation or processing of the sensor signal either may be deactivated entirely or may be carried out only with a very low required power. For this purpose, for example, a unit for processing or preparing the sensor signals may be put into a sleep mode or into an operating mode with very low energy consumption.

The sensor that may provide a sensor signal at the input terminal of the device for processing the sensor data may be any arbitrary sensor. In particular, any arbitrary sensors are possible which detect one or multiple surroundings parameters, such as for example a temperature, a pressure, a humidity, a brightness, or any arbitrary other value, and output a sensor value corresponding to the detected parameter. The sensor value may be provided in any arbitrary form, in particular as any arbitrary analog signal. For example, a current corresponding to the parameter monitored by the sensor, or a corresponding voltage may be output.

In accordance with an example embodiment of the present invention, the differentiating device may be connected directly to the input terminal of the device for processing the sensor data in order to receive the sensor signal provided by the sensor. A suitable coupling device may optionally be provided between the input terminal and the differentiating device. Such a coupling device may for example convert the sensor signal provided by the sensor into a signal which corresponds to the sensor signal and which is suitable for further processing. For example, a current signal provided by the sensor may be converted into a corresponding voltage signal, or a voltage signal may be converted into a corresponding current signal. A galvanic separation or the like is optionally also possible if necessary.

The differentiating device may monitor the sensor signal provided by the sensor. In particular, the differentiating device may for example carry out a temporal differentiation. In this case, the differentiating device may ascertain a change in the sensor signal, in particular a change in the sensor signal over time. For example, the differentiating device may ascertain whether the sensor signal deviates from a predefined value by more than a threshold value, or whether the sensor signal changes by more than a predefined threshold value within a predetermined period of time. If such a deviation is detected, the differentiating device may for example output a signaling to this effect. Alternatively, the differentiating device may also output a signal that corresponds to the temporal change in the monitored sensor signal.

The differentiation, i.e., the monitoring of a temporal change in the sensor signal, may in particular take place either in the analog domain, i.e., on the basis of a sensor signal received in analog form, or in the digital domain, i.e., on the basis of a digitized sensor signal. If the monitoring of the sensor signal takes place in the analog domain, all downstream further components, in particular including an analog-to-digital converter, may optionally be deactivated for as long as no change or no significant temporal change in the sensor signal in the analog domain is detected. If, in contrast, the monitoring of the sensor signal takes place in the digital domain, the upstream components, such as for example an analog-to-digital converter, must be activated at least temporarily in order to be able to provide the required digital signal.

In accordance with an example embodiment of the present invention, based on the evaluation of the sensor signal by the differentiating device, the operation of the sensor device may be adapted. For this purpose, a suitable operating state may be selected for example from multiple possible operating states of the sensor device, in each case as a function of the detected temporal change in the sensor signal, and the sensor device may then be set accordingly. For example, a sleep mode may be provided in the sensor device, in which the sensor device has only a minimal energy consumption. For example, no processing of the sensor signal from the sensor may be carried out in this sleep mode. Furthermore, an operating state, in which the sensor signal is processed continuously or cyclically from the sensor in predetermined time intervals, may be provided in the sensor device. In particular, it may for example be provided that one or multiple operating parameters of the sensor device are adapted as a function of the temporal change in the sensor signal. For example, a sampling rate for an analog-to-digital conversion may be adapted as a function of the value of the temporal change in the sensor signal. In addition, further operating parameters, such as for example a processing speed or the like, may also be adapted as a function of the value of the temporal change in the sensor signal.

In this way, it is therefore possible to minimize the energy consumption for processing the sensor signal if the sensor signal does not change or changes only a little. At the same time, it may be ensured that, in the event of significant changes in the sensor signal, a sufficiently accurate processing of the sensor signal is always ensured by adapting the operating parameters of the digital signal processing accordingly.

Further embodiments, refinements and implementations of the present invention include combinations, even when not mentioned explicitly, of features of the present invention which have been described above or which will be described below in relation to the exemplary embodiments. In particular, a person skilled in the art will also add individual aspects as improvements or additions to the respective basic forms of the present invention, in view of the disclosure herein. As far as is reasonable, the described embodiments and refinements may be arbitrarily combined with one another.

### BRIEF DESCRIPTION OF THE DRAWINGS

Further features and advantages of the present invention are explained below with reference to the figures.

FIG. 1 shows a block diagram of a sensor device including a circuit arrangement for automatically controlling the energy consumption according to one specific example embodiment of the present invention.

FIG. 2 shows a flowchart based on a method for automatically controlling the energy consumption of a sensor device according to one specific example embodiment of the present invention.

### DETAILED DESCRIPTION OF EXAMPLE EMBODIMENTS

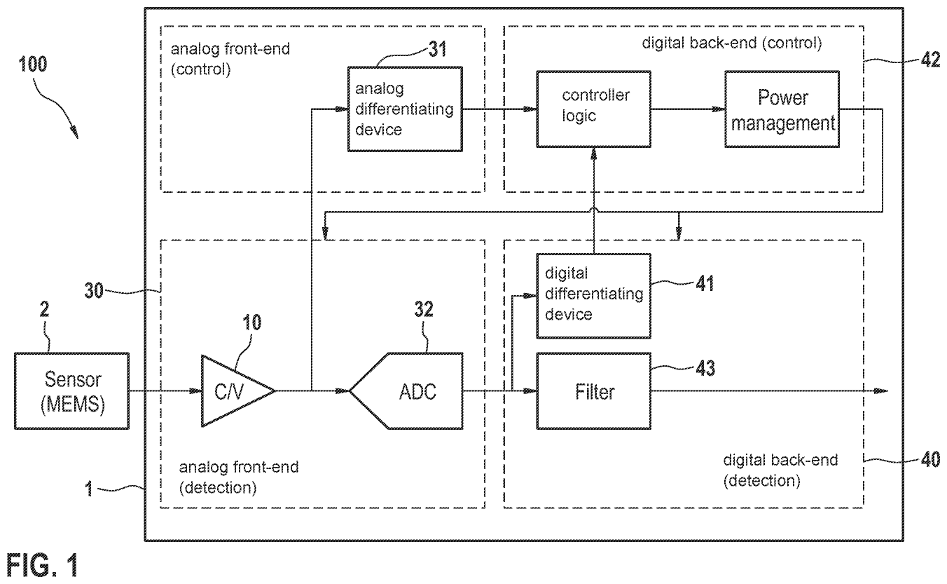

FIG. 1 shows a schematic illustration of a sensor device 100 according to one specific example embodiment of the present invention. Sensor device 100 includes at least one sensor 2 and circuit arrangement 1 for controlling the energy consumption of sensor device 100. Sensor 2 may be any arbitrary sensor which sensorially detects one or multiple parameters, such as for example temperature, pressure, humidity, brightness, speed, acceleration, or any arbitrary other parameter. For example, sensor 2 may be a micromechanical pressure sensor element, an acceleration sensor element, a rotation rate control sensor element, or a magnetic sensor element.

In the exemplary embodiment shown here, the parameter is detected capacitively and is converted into an analog sensor signal by a capacitance/voltage converter 10. However, any arbitrary other way of providing the analog sensor signal is of course also possible.

Circuit arrangement 1 include an analog front-end circuit 30. Capacitance/voltage converter 10 is part of this analog front-end circuit 30, which further includes an analog-to-digital converter 32 with variable sampling rate and resolution. By way of this analog-to-digital converter 32, the analog sensor signal is converted into a digital sensor signal.

Further processing of the digitized sensor signal may take place for example in a digital back-end circuit 40, which is likewise part of circuit arrangement 1. For example, digital back-end circuit 40 may include any arbitrary suitable components, such as for example a digital filter 43 including variable filter parameters which is arranged downstream of analog-to-digital converter 32. Any additional arbitrary components, such as for example an amplifier, a first-in first-out (FIFO) memory or an output interface, are of course possible. In particular, the processed sensor signal may be transferred to one or multiple further devices via a wired or wireless interface. The transfer may in this case take place using any arbitrary suitable format or protocol.

According to the example embodiment of the present invention, circuit arrangment 1 include at least one differentiating device 31, 41 that monitors the analog and/or the digitized sensor signal and detects a temporal change in the sensor signal. In the exemplary embodiment shown here, an analog differentiating device 31 is provided, which monitors the analog sensor signal provided by capacitance/voltage converter 10 and detects a change in the analog sensor signal, for example a deviation of the sensor signal by more than a predefined threshold value or a change in the sensor signal by more than a predefined value within a predetermined period of time. Here, a digital differentiating device 41 is additionally provided in digital back-end circuit 40, which detects a change in the digitized sensor signal.

The deviation determined by analog differentiating device 31 and/or digital differentiating device 41, in particular the deviation of the sensor signal over time, is provided to a control device 42 that is designed to select and set one of multiple predefined operating modes of sensor device 100 as a function of the temporal change in the sensor signal. For this purpose, control device 42 may vary the operation of individual components of sensor device 100, in particular the operating mode of analog-to-digital converter 32 and/or of filter 43, in particular in digital back-end circuit 40 as a function of the ascertained change in the sensor signal.

For example, control device 42 may put the corresponding components of sensor device 100 into a sleep mode if the analog sensor signal does not change or at least does not change significantly. For example, control device 42 may put analog-to-digital converter 32 and/or components 41 and 43 in digital back-end circuit 40 into the sleep mode for as long as the analog sensor signal does not change by more than a predefined threshold value. Alternatively, the corresponding components may also remain in the sleep mode for as long as the analog sensor signal does not change by more than a predefined threshold value within a predefined period of time. Any other criteria for maintaining the sleep mode or setting the sleep mode are of course also possible.

If a predetermined event is detected on the basis of the monitoring by at least one of differentiating devices 31, 41, for example a deviation of the sensor signal by more than a predetermined value or a deviation of the sensor signal by more than a predetermined value within a predetermined period of time, control device 42 selects a different predefined operating mode for sensor device 100 and initiates the switch to this different operating mode. For this purpose, control device 42 may for example activate analog-to-digital converter 32 and/or the necessary further components to carry out any arbitrary operations, such as for example an analog-to-digital conversion, filtering, storing, data transfer or the like.

To further optimize the operating behavior of sensor device 100, in particular to optimize the energy consumption, it is additionally also possible to dynamically adapt one or multiple settings of the components of sensor device 100, such as for example of analog-to-digital converter 32. For example, a clock rate for processing the digitized sensor data within sensor device 100, in particular in digital back-end circuit 40, may be adapted as a function of the change in the sensor signal determined by analog and/or digital differentiating device 31, 41. For example, the data may be processed at a higher processing rate if a rapid change in the sensor signal has been detected by differentiating devices 31, 41. Conversely, the processing rate may be reduced if differentiating devices 31, 41 have detected that the sensor signal is changing only slowly.

In addition or as an alternative, it is also possible for example to adapt operating parameters, such as for example a sampling rate of an analog-to-digital converter 32, as a function of the rate of change in the sensor signal. For example, the sampling rate of analog-to-digital converter 32 may be increased if analog and/or digital differentiating device 31, 41 establishes that the sensor signal at input terminal 10 is changing rapidly. Analogously, the sampling rate of analog-to-digital converter 32 may be reduced if the sensor signal is changing more slowly. Of course, any other arbitrary parameters that may be dynamically adapted as a function of the temporal change in the sensor signal at input terminal 10 are also possible.

If the analog sensor signal is not changing or at least is not changing significantly, then optionally analog-to-digital converter 32 and/or further components of sensor device 100, in particular of digital back-end circuit 40, may be put into the sleep mode. In this sleep mode, for example, the processing of the sensor data may then be limited or optionally even abandoned entirely. For example, it is possible that no processing of sensor data takes place during the sleep mode. Alternatively, it is also possible for example that a limited processing of sensor signals takes place in a sleep mode. For example, an optional brief processing of sensor signals may take place cyclically even in the sleep mode. For example, a processing of the sensor signals may take place for a predetermined period of time. The processing of the sensor signals may subsequently be paused for a further period of time, in order to process the sensor signals thereafter again for a predetermined period of time. In this way, an at least limited further processing of the sensor signals may take place even in the case of constant sensor signals or sensor signals that are changing only a little.

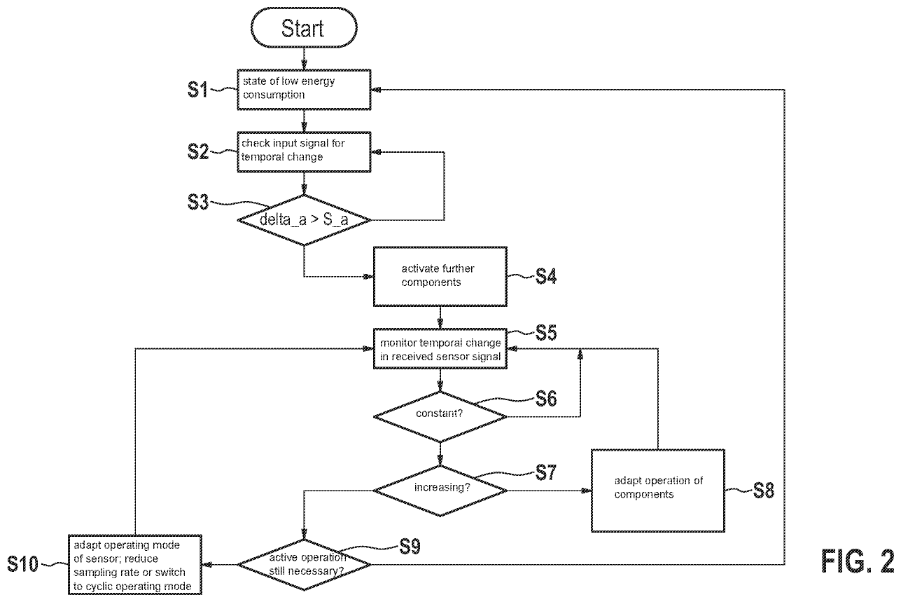

FIG. 2 shows a flowchart based on a method for controlling the energy consumption of a sensor device 100 according to one specific example embodiment of the present invention. The method may include any arbitrary steps as already described above in connection with sensor device 100. Analogously, sensor device 100 may also include any arbitrary components suitable for implementing the method described below.

The method may in particular be applied to a sensor device 100 including a sensor element 2, an analog front-end circuit 30, and a digital back-end circuit 40.

At the start, in step Sl, the method may initially be in a state of particularly low energy consumption (Ultra Low Power, ULP). For example, all components apart from input interface 10 may be deactivated. As the method continues, for example in step S2, an analog differentiating device 31 may be activated to check an input signal for a possible temporal change. Here, analog differentiating device 31 may be operated for example in continuous operation over a relatively long period of time. Alternatively, it is also possible that analog differentiating device 31 is activated only cyclically for predetermined time intervals in each case, and then is deactivated thereafter for further predetermined time intervals in each case.

In step S3, a check may be carried out as to whether the magnitude of a temporal change delta_a in the received analog signal exceeds a predefined threshold value S_a. If the magnitude of the temporal change delta_a is less than the predefined threshold value S_a, the components of sensor device 100 remain in their up-to-date state. Otherwise, if the magnitude delta_a of the temporal change in the analog input signal exceeds the predefined threshold value S_a, further components of sensor device 100 may be activated in step S4. For example, an analog-to-digital converter 32 of analog front-end circuit 30 may be activated. Furthermore, components of digital back-end circuit 40 may also be activated.

In step S5, with back-end circuit 40 activated, a temporal change in the received sensor signal may be monitored in the digital domain by a digital differentiating device 41. If it is established in step S6 that the temporal change in the digitized sensor signal is approximately constant, the system may maintain its present operating state. Otherwise, a check may be carried out in step S7 as to whether the temporal change in the received sensor signal has increased or decreased.

If it is established in step S7 that the temporal change in the sensor signal is increasing further, the operation of the components in sensor device 100, in particular in analog-to-digital converter 32 or in digital back-end circuit 40, may be adapted accordingly for example in step S8. For example, a sampling rate for the analog-to-digital conversion in analog-to-digital converter 32 may be increased. If some components, for example components of digital back-end circuit 40, are being operated in a cyclic operation, the duty cycle of the cyclic operation may be adapted if it is detected that the temporal change in the sensor signal is increasing. For example, the pauses between two active operating periods may be shortened. Furthermore, a switch from cyclic operation to continuous operation may also take place for example.

If, in contrast, it is established in step S7 that the temporal change in the sensor signal is decreasing compared to the previous point in time, then initially a check may be carried out in step S9 as to whether an active operation of sensor device 100 is still necessary. If, for example, it is established in step S7 that the temporal change in the received sensor signal has fallen below a corresponding threshold value or other criteria are met (and the amplitude of the received sensor signal has fallen below a predefined threshold value), thereby justifying an at least partial deactivation of sensor device 100, sensor device 100 may be switched to the ultra low power mode described above.

If, in contrast, it is established in step S9 that the temporal change in the received sensor signal has decreased only a little, the operating mode of sensor device 100 may be adapted accordingly. For example, in step S10, a sampling rate of analog-to-digital converter 32 may be reduced. If all or at least some of the components of sensor device 100 are in a continuous operating mode, then in step S10 the continuous operating mode may optionally also be switched to a cyclic operating mode, in which at least some of the components are activated only temporarily and are thereafter deactivated for a predetermined period of time. If at least some of the components of sensor device 100 are already being operated in a cyclic operating mode, the operating parameters of this cyclic operation may optionally also be adapted. For example, the pauses between two active phases may be increased, or the operating duration of the active phases may be shortened.

In summary, the present invention relates to an energy-efficient sensor device, to a circuit arrangement for operating an energy-efficient sensor device, and to a method for controlling the energy consumption of a sensor device. In particular, the operating mode of a sensor device is adapted as a function of a temporal change in a received sensor signal.

What is claimed is:

1. A circuit arrangement for automatically controlling the energy consumption of a sensor device, the circuit arrangement being part of the sensor device, and the circuit arrangement comprising:
an analog front-end circuit including an analog-to-digital converter configured to read out an analog sensor signal detected by a sensor element and to convert the analog sensor signal into a digital sensor signal;
a digital back-end circuit configured to process the digital sensor signal;
at least one differentiating device configured to ascertain a temporal change in the sensor signal; and
a control device configured to select and set one of multiple predefined operating modes of the sensor device as a function of the temporal change in the sensor signal.

2. The circuit arrangement as recited in claim 1, wherein the at least one differentiating device includes an analog differentiating device configured to 31 ascertain a temporal change in the analog sensor signal, the control device being configured to select and set one of multiple predefined operating modes of the sensor device as a function of the temporal change in the analog sensor signal.

3. The circuit arrangement as recited in claim 1, wherein the at least one differentiating device includes a digital differentiating device configured to ascertain a temporal change in the digital sensor signal, wherein the control device is configured to select and set one of the predefined operating modes of the sensor device as a function of the temporal change in the digital sensor signal.

4. The circuit arrangement as recited in claim 1, wherein at least one energy-saving mode, in which the sensor device is deactivated at least in part and/or at times, may be set as the operating mode of the sensor device.

5. The circuit arrangement as recited in claim 2, wherein at least one of the following energy-saving modes are settable as one of the predefined operating modes:
cyclic operation of the sensor device, with components of the sensor device being activated and deactivated in an alternating manner in predefined, successive time intervals in cyclic operation;
continuous operation of the analog differentiating device, of the control device, and of the analog front-end circuit, without the analog-to-digital converter, while the digital back-end circuit is deactivated;
cyclic operation of the analog differentiating device, of the control device, and of the analog front-end circuit, without the analog-to-digital converter, while the digital back-end circuit is deactivated.

6. The circuit arrangement as recited in claim 1, wherein, in order to set one of the predefined operating modes of the sensor device, the control device is configured to:
selectively activate and deactivate the analog-to-digital converter of the analog front-end circuit and at least parts of the digital back-end circuit; and/or
vary a sampling rate at which the analog sensor signal is sampled during the conversion into a digital sensor signal, by actuating the analog-to-digital converter and/or a downstream filter of the analog front-end circuit; and/or
vary time intervals of a cyclic operation of individual components of the sensor device; and/or
maintain a continuous operation of individual components of the sensor device.

7. A sensor device, comprising:
a sensor element for detecting a sensor signal, the sensor element including a micromechanical pressure sensor element, and/or an acceleration sensor element, and/or a rotation rate sensor element, and/or a magnetic sensor element; and
a circuit arrangement configured to automatically controlling energy consumption of the sensor device, the circuit arrangement including:
an analog front-end circuit including an analog-to-digital converter configured to read out an analog sensor signal detected by the sensor element and to convert the analog sensor signal into a digital sensor signal,
a digital back-end circuit configured to process the digital sensor signal,
at least one differentiating device configured to ascertain a temporal change in the sensor signal, and
a control device configured to select and set one of multiple predefined operating modes of the sensor device as a function of the temporal change in the sensor signal.

8. A method for automatically controlling the energy consumption of a sensor device, the sensor device including at least one sensor element configured to detect an analog sensor signal, an analog front-end circuit with an analog-to-digital converter configured to read out the detected analog sensor signal and to convert the detected analog sensor signal into a digital sensor signal, a digital back-end circuit configured to process the digital sensor signal, and a control device configured to automatically set one of multiple predefined operating modes of the sensor device, the method comprising the following steps:
continuously monitoring a temporal change in the sensor signal; and
depending on the temporal change in the sensor signal, either maintaining a present operating mode or setting a different predefined operating mode.

9. The method as recited in claim 8, wherein the temporal change in the analog sensor signal is monitored, and when the sensor device is in an energy-saving mode in which the analog sensor signal is not being converted into a digital sensor signal and/or the temporal change in the digital sensor signal is not being determined, and a different operating mode is set only when the temporal change in the analog sensor signal exceeds a predefined threshold value for a predefined duration.

10. The method as recited in claim 9, wherein, when the sensor device is in the energy-saving mode and the temporal change in the analog sensor signal exceeds a predefined threshold value for a predefined duration, a different operating mode is set in which at least the analog-to-digital converter of the analog front-end circuit and a digital differentiating device for the digital sensor signal are activated at least at times.

11. The method as recited in claim 8, wherein the temporal change in the digital sensor signal is monitored, and when the sensor device is in an operating mode in which the analog sensor signal is being converted into a digital sensor signal and the temporal change in the digital sensor signal is being determined, a different operating mode is set only when the temporal change in the digital sensor signal exceeds or falls below a predefined threshold value for a predefined duration.

12. The method as recited in claim 11, wherein, when the temporal change in the digital sensor signal exceeds the predefined threshold value for the predefined duration, a different operating mode is set by:
increasing a sampling rate at which the analog sensor signal is sampled during the conversion into the digital sensor signal, and/or
varying a length of time intervals of a cyclic operation of individual components of the sensor device; and/or
maintaining a continuous operation of at least individual components of the sensor device.

13. The method as recited in claim 11, wherein, when the temporal change in the digital sensor signal falls below the predefined threshold value for the predefined duration, a check is carried out as to whether an up-to-date level of the sensor signal corresponds to a level of the sensor signal in the energy-saving mode.

14. The method as recited in claim 13, wherein, wherein the up-to-date level of the sensor signal corresponds to the level of the sensor signal in the energy-saving mode, the energy-saving mode is set as the new operating mode.

15. The method as recited in claim 13, wherein, when the up-to-date level of the sensor signal does not correspond to the level of the sensor signal in the energy-saving mode, a different operating mode is set by:
reducing a sampling rate of the sensor signal; and/or
switching to a cyclic operation of individual components of the sensor device; and/or
varying a length of time intervals of a cyclic operation of individual components of the sensor device.
